(19) United States
(12) Patent Application Publication
(10) Pub. No.: US 2013/0055553 A1
(43) Pub. Date: Mar. 7, 2013

(54) SYSTEMS AND METHODS FOR GROUPING BATTERIES

(71) Applicant: Wei ZHANG, Shanghai (CN)

(72) Inventor: Wei ZHANG, Shanghai (CN)

(73) Assignee: O2MICRO INC., Santa Clara, CA (US)

(21) Appl. No.: 13/565,998

(22) Filed: Aug. 3, 2012

(30) Foreign Application Priority Data
Sep. 5, 2011 (CN) 201110269206.0

(51) Int. Cl. G01R 31/36; H01M 10/12

(52) U.S. Cl. 29/593; 324/434

(57) ABSTRACT

Methods and systems for grouping multiple battery modules in a battery pack are disclosed. Multiple characteristic parameters of multiple cells in a battery module of the battery modules are measured to produce a measured result. Multiple differences between the multiple characteristic parameters are calculated according to the measured result. The battery module is classified according to the multiple differences.

### RELATED APPLICATION

The present application claims priority to Patent Application No. 201110269206.0, filed on Sep. 5, 2011, with the State Intellectual Property Office of the People's Republic of China.

### BACKGROUND

Lead-acid batteries have been under development for over one hundred years and are widely applied in the domain of electrical bicycles and electrical vehicles. Generally, the rated voltage of a lead-acid battery cell is 2V, and a lead-acid battery module that has a rated voltage of 12V or 16V includes six or eight cells coupled in series. Multiple series-coupled 12V or 16V lead-acid battery modules constitute a 36V, 48V, 60V or 64V lead-acid battery pack which can serve as a power source for electrical bicycles and electrical vehicles in the market.

Usually, the lifespan of a lead-acid battery module is around one to one-and-a-half years, which is rather short considering its application in the domain of electrical bicycles and electrical vehicles. In addition, the voltage drop of a cell in the lead-acid battery module caused by over-discharging the cell is likely to drastically reduce the lifespan of the lead-acid battery module. Additionally, the conventional grouping technology for the lead-acid battery modules is incapable of identifying the voltage drops in cells caused by over-discharging the cells, and thus the conventional grouping technology cannot prolong the lifespan of the lead-acid battery module efficiently.

FIG. 1 illustrates a diagram of a conventional method for grouping lead-acid battery modules by manually measuring module discharge voltages of the lead-acid battery modules. Taking 12V lead-acid battery modules for example, the conventional method for grouping the lead-acid battery modules includes the following steps: the manufacturer performs charge/discharge tests cyclically for the lead-acid battery modules during the battery manufacturing phase or factory test phase; during the charge/discharge tests, an operator manually measures the module discharge voltages of the lead-acid battery modules as shown in FIG. 1; and the operator selects the lead-acid battery modules which are suitable to be grouped into a battery pack according to the measured module discharge voltages. This conventional method for grouping the lead-acid battery modules is conducted based on using manual measurements of module discharge voltages of the lead-acid battery modules, and thus the condition of each cell included in the lead-acid battery modules cannot be taken into account.

More specifically, during the battery manufacturing phase or factory test phase, the manufacturer discharges the lead-acid battery modules by the rated charge capacities of the lead-acid battery modules, and then measures the module discharge voltages of the lead-acid battery modules after a period of time from the discharging of the lead-acid battery modules. For example, if a 48V lead-acid battery pack is to be assembled, then four 12V lead-acid battery modules need to be selected. At the beginning, the four lead-acid battery modules are fully charged and the rated charge capacity of each battery module is 20 Ah. During the grouping process, each of the full-charged lead-acid battery modules is discharged by about 20 Ah. After a period of time (e.g., a half or one hour) from the discharging, the module discharge voltage for each of the lead-acid battery modules is measured, and the lead-acid battery modules which satisfy the grouping requirements are selected based on the result of the most recent measurement. To assemble or group lead-acid battery modules in a battery pack, the lead-acid battery modules should satisfy the following grouping requirements:

(1) the module discharge voltage for each lead-acid battery module is greater than a predetermined threshold, e.g., 10.5V; and

(2) the difference between the module discharge voltages of every two lead-acid battery modules is within a predetermined limit, e.g., 50 mV. If the difference between the module discharge voltages of any two of the lead-acid battery modules is greater than the predetermined limit, the lead-acid battery modules should not be assembled or grouped as a battery pack.

FIG. 2 illustrates a diagram of grouping requirements for conventional grouping technology for lead-acid battery modules. As shown in FIG. 2, the module discharge voltage of the lead-acid battery module M13 is less than the predetermined threshold 10.5V, and the difference between the module discharge voltages of the lead-acid battery modules M13 and M14 is greater than the predetermined limit 50 mV. Therefore, according to the grouping requirements mentioned above, the lead-acid battery modules M11˜M14 will not be grouped in a lead-acid battery pack. Furthermore, the lead-acid battery modules Mn1˜Mn4 satisfy the aforementioned grouping requirements, so that they can be coupled in series to form a 48V lead-acid battery pack.

Disadvantageously, however, each lead-acid battery module includes multiple internal cells and the differences between the module discharge voltages of the lead-acid battery modules do not reflect the differences between cell voltages of the individual cells included in the lead-acid battery modules. Consequently, the conventional grouping technology for lead-acid batteries cannot precisely recognize the voltage drops in the cells that are caused by over-discharging the cells. This may result in the reduction of lifespan of the lead-acid battery pack.

### SUMMARY

In one embodiment, a method for grouping a plurality of battery modules in a battery pack is disclosed. The method includes: measuring a plurality of characteristic parameters of a plurality of cells in a battery module of the plurality of battery modules to produce a measured result; calculating a plurality of differences between the plurality of characteristic parameters according to the measured result; and classifying the battery module according to the plurality of differences.

In another embodiment, a system for grouping a plurality of battery modules in a battery pack is disclosed. The system includes a detection apparatus and a controller. The detection apparatus is configured to measure a plurality of characteristic parameters of a plurality of cells in a battery module of the plurality of battery modules to produce a measured result, and calculate a plurality of differences between the plurality of characteristic parameters according to the measured result. The controller is configured to classify the battery module according to the plurality of differences.

In yet another embodiment, a system for grouping a plurality of battery modules in a battery pack is disclosed. The system includes a plurality of detecting terminals and a detection circuit. The plurality of detecting terminals are each coupled to a cell of a plurality of cells in a battery module of said plurality of battery modules. The detection circuit, coupled to the plurality of detecting terminals, includes a detection unit and a controller. The detection unit is configured to measure a plurality of characteristic parameters of the plurality of cells to produce a measured result, and calculate a plurality of differences between the plurality of characteristic parameters according to the measured result. The controller is configured to classify the battery module to a corresponding class of a plurality of classes according to the plurality of differences.

Additional advantages and novel features will be set forth in part in the description which follows, and in part will become apparent to those skilled in the art upon examination of the following and the accompanying drawings or may be learned by production or operation of the disclosed embodiments. The advantages of the present embodiments may be realized and attained by practice or use of various aspects of the methodologies, instrumentalities and combinations set forth in the detailed description set forth below.

### BRIEF DESCRIPTION OF THE DRAWINGS

Features and advantages of embodiments of the claimed subject matter will become apparent as the following detailed description proceeds, and upon reference to the drawings, wherein like numerals depict like parts. These exemplary embodiments are described in detail with reference to the drawings. These embodiments are non-limiting exemplary embodiments, in which like reference numerals represent similar structures throughout the several views of the drawings.

FIG. 1 illustrates a diagram of a conventional method for grouping lead-acid battery modules by manually measuring module discharge voltages of the lead-acid battery modules.

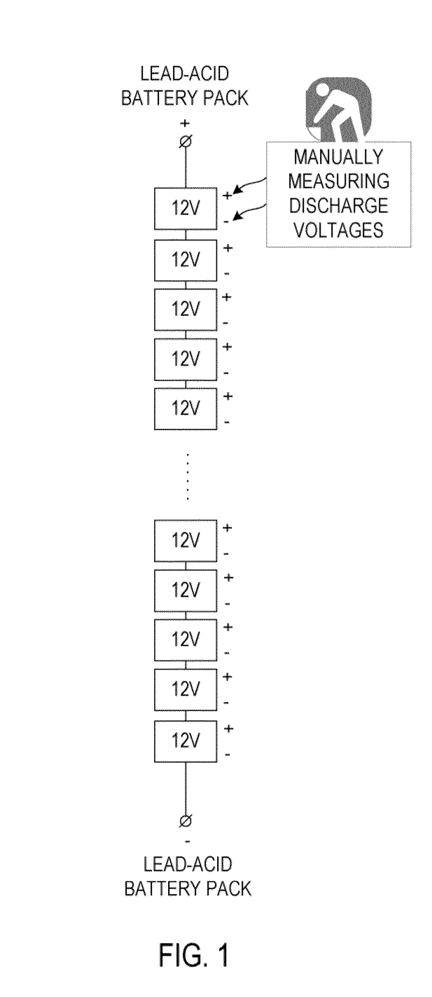

FIG. 2 illustrates a diagram of grouping requirements for conventional grouping technology for lead-acid battery modules.

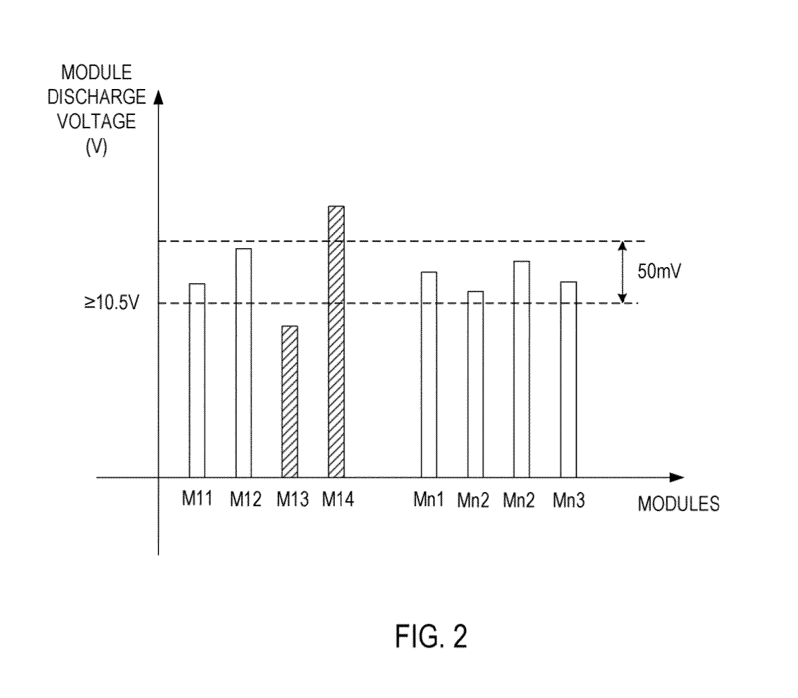

FIG. 3 illustrates a block diagram of an exemplary lead-acid battery grouping system, in accordance with one embodiment of the present teaching.

FIG. 4 illustrates a diagram of exemplary requirements for grouping lead-acid battery modules, in accordance with one embodiment of the present teaching.

FIG. 5 illustrates a block diagram of an exemplary lead-acid battery grouping system for grouping multiple lead-acid battery packs, in accordance with one embodiment of the present teaching.

### DETAILED DESCRIPTION

Reference will now be made in detail to the embodiments of the present teaching. While the present teaching will be described in conjunction with these embodiments, it will be understood that they are not intended to limit the present teaching to these embodiments. On the contrary, the present teaching is intended to cover alternatives, modifications and equivalents, which may be included within the spirit and scope of the present teaching as defined by the appended claims.

Furthermore, in the following detailed description of the present teaching, numerous specific details are set forth in order to provide a thorough understanding of the present teaching. However, it will be recognized by one of ordinary skill in the art that the present teaching may be practiced without these specific details. In other instances, well known methods, procedures, components, and circuits have not been described in detail as not to unnecessarily obscure aspects of the present teaching.

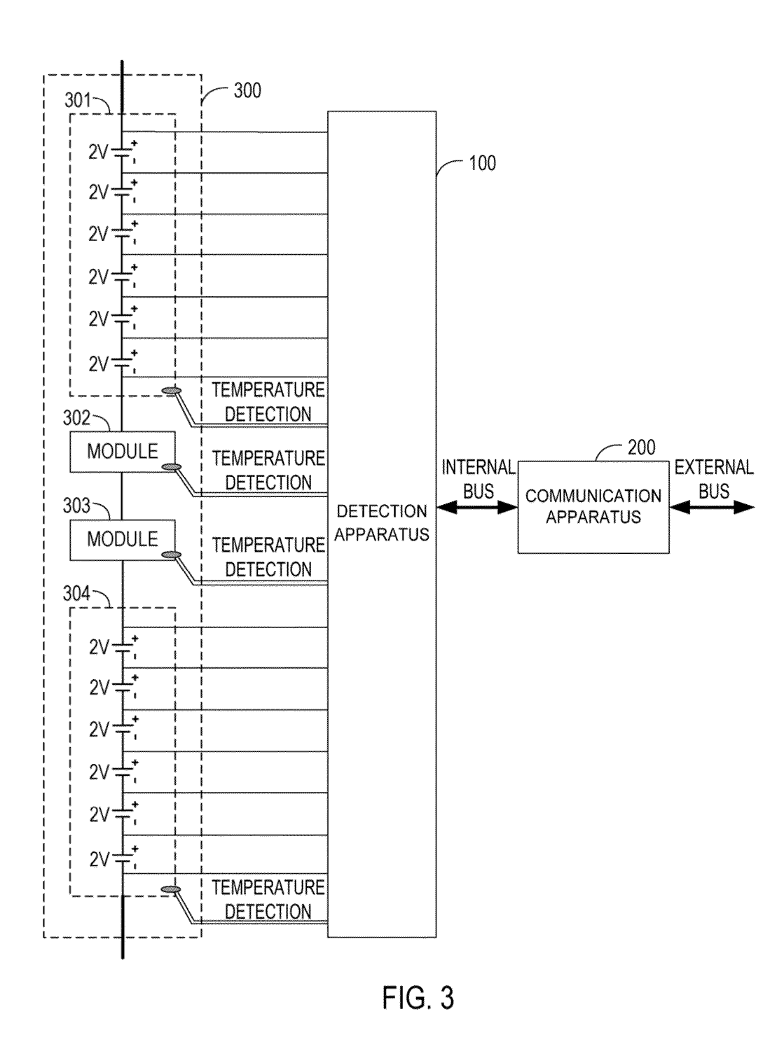

FIG. 3 illustrates a block diagram of an exemplary lead-acid battery grouping system, e.g., for grouping four 12V lead-acid battery modules in a 48V lead-acid battery pack 300, in accordance with one embodiment of the present teaching. As shown in FIG. 3, the lead-acid battery pack 300 includes series-coupled lead-acid battery modules 301, 302, 303 and 304. Each of the lead-acid battery modules 301, 302, 303 and 304 includes six series-coupled cells, and every cell is coupled to a detection apparatus 100. The detection apparatus 100 measures a cell discharge voltage for each of the cells, and transfers a measured result to a communication apparatus 200 via an internal bus. The communication apparatus 200 is also coupled to an external controller (not shown) via an external bus and transfers the measured result to the external controller. According to the measured result of the cell discharge voltage, the external controller classifies the lead-acid battery modules 301, 302, 303 and 304 by checking whether each of the battery module 301, 302, 303, or 304 satisfies the grouping requirements (as detailed below) and which grouping requirement the battery module matches to.

FIG. 3 shows the structures of the series-coupled cells inside the lead-acid battery modules 301 and 304, and it is understood by one skilled in the art that the lead-acid battery modules 302 and 303 can have similar structures. Moreover, FIG. 3 discloses a 48V lead-acid battery pack, and a corresponding detection apparatus 100 that supports simultaneous detection for a status of each of the 24 cells (each lead-acid battery module 301, 302, 303, and 304 includes 6 cells). The detection apparatus 100 includes 24 detecting channels. However, it will be acknowledged by one of ordinary skill in the art that this description is not intended to limit the detection apparatus 100, and the detection apparatus 100 can include any number of detecting channels depending on different applications and different requirements. For example, in order to constitute a 64V lead-acid battery pack, four 16V lead-acid battery modules are coupled in series, with each lead-acid battery module including eight cells. Accordingly, the detection apparatus 100, in this example would include 32 detecting channels.

In one embodiment, the detection apparatus 100 also detects the temperature of the lead-acid battery modules 301, 302, 303, and 304 during the battery manufacturing phase. As shown in FIG. 3, the temperature of the lead-acid battery modules 301, 302, 303 and 304 are detected to ensure a comparable temperature condition in all the lead-acid battery modules 301, 302, 303 and 304, so that the accuracy of voltage measurement can be improved. Detection apparatus 100 may also detect a temperature of the lead-acid battery modules 301, 302, 303, and 304 in order to ensure a stable temperature condition, e.g., a constant temperature condition, to measure the cell discharge voltages of each of the lead-acid battery modules 301, 302, 303, and 304.

As mentioned above, the detection apparatus 100 generates a measured result indicative of the cell discharge voltages of the cells. According to the measured result indicative of the cell discharge voltages, the aforementioned external controller classifies the lead-acid battery modules 301, 302, 303 and 304 by checking whether each of the battery module 301, 302, 303, or 304 satisfies the grouping requirements (as detailed below) and which grouping requirement the battery module matches to.

At the beginning of the classifying operation, in one embodiment, the lead-acid battery modules 301, 302, 303 and 304 (e.g., each having a rated charge capacity of 20 Ah) are fully charged. During the classifying process, each of the full-charged lead-acid battery modules 301, 302, 303 and 304 is discharged by its rated charge capacity (e.g., 20 Ah). After a certain period of time from the discharging of the battery modules 301, 302, 303 and 304, the detection apparatus 100 measures the cell discharge voltage for each cell in the battery modules 301, 302, 303 and 304. In one embodiment, the cell discharge voltage of each cell is greater than or equal to a preset threshold (e.g., 1.75V). In this case, the lead-acid battery module can be classified in the following processes. If the difference between the cell discharge voltages of every two cells in the lead-acid battery module is equal to or less than 20 mV, then the lead-add battery module is classified to a first class in which the products are deemed optimal. If the maximum value of the differences between the cell discharge voltages of the cells in the lead-acid battery module falls within a range 20 mV˜35 mV, the lead-acid battery module is classified to a second class in which the products are deemed sub-optimal. If the maximum value of the differences between the cell discharge voltages of the cells in the lead-acid battery module falls within a range 35 mV˜50 mV, the lead-acid battery module is classified to a third class in which the products are deemed qualified. If the maximum value of the differences between the cell discharge voltages of the cells in the lead-acid battery module is greater than 50 mV, the lead-acid battery module is classified to a fourth class in which the products are deemed unqualified.

Advantageously, during the battery manufacturing phase, the cell discharge voltages of the cells in the lead-acid battery modules 301, 302, 303, and 304 are measured, and the lead-acid battery modules 301, 302, 303, and 304 are classified according to the measured result. Based on the classification of the lead-acid battery modules 301, 302, 303, and 304, the battery manufacturer can be more productive by increasing the product qualified rate. For example, the battery manufacturer can adjust the amount of acid injection of cells in a lead-add battery module which is classified in the unqualified fourth class, such that the lead-acid battery module can be classified in the qualified third class after the adjustment. Similarly, the battery manufacturer can adjust the amount of acid injection of cells in a lead-acid battery module which is classified in a lower class (the fourth class is lower than the third class, and the third class is lower than the second class, etc.), such that the lead-acid battery module can be classified to a higher class after the adjustment. Furthermore, the present lead-acid battery grouping method and system described in accordance with the embodiments herein, classify the lead-acid battery modules in accordance with the condition of cells included therein, thus the grouping of the lead-add battery modules is implemented more accurately.

In one embodiment, the grouping requirements for grouping lead-acid battery modules and the method for classifying the lead-acid battery modules are detailed as follows:

(a) the cell discharge voltage for each cell in the lead-acid battery module is determined to be greater than a preset threshold, e.g., 1.75V;

(b) if the differences between the cell discharge voltages of the cells in the lead-acid battery module are all equal to or less than a first predefined limit (e.g., 20 mV), then the lead-acid battery module is classified to the first class;

(c) if the maximum value of the differences between the cell discharge voltages of the cells in the lead-acid battery module is greater than the first predefined limit (e.g., 20 mV) and is equal to or less than a second predefined limit (e.g., 35 mV), the lead-acid battery module is classified to the second class;

(d) if the maximum value of the differences between the cell discharge voltages of the cells in the lead-acid battery module is greater than the second predefined limit (e.g., 35 mV) and is equal to or less than a third predefined limit (e.g., 50 mV), the lead-acid battery module is classified to the third class; and

(e) if the maximum value of the differences between the cell discharge voltages of the cells exceeds the third predefined limit (e.g., greater than 50 mV), the lead-acid battery module is classified as an unqualified product.

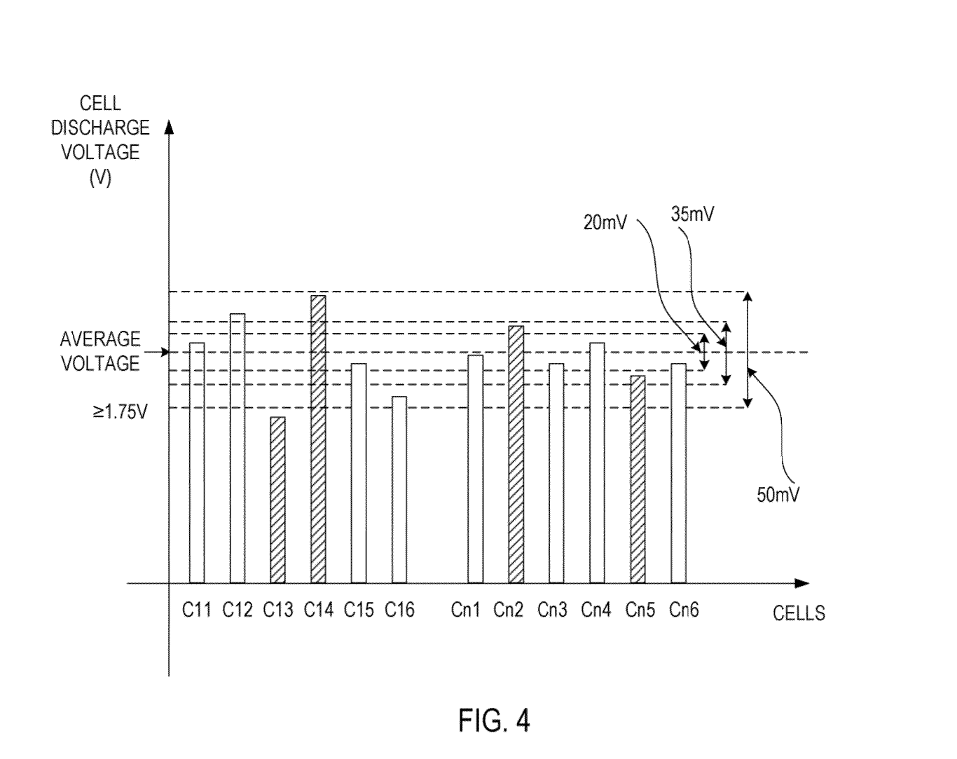

FIG. 4 illustrates a diagram of exemplary requirements for grouping lead-acid battery modules, in accordance with one embodiment of the present teaching. According to the grouping requirements mentioned above, since the cell discharge voltage of the cell C13 is less than the preset threshold 1.75V, and the difference between cell discharge voltages of the cells C13 and C14 is greater than the third predefined limit 50 mV, the lead-acid battery module including the cells C11˜C16 is unqualified and unsuitable to be grouped in a lead-acid battery pack. Furthermore, the cell discharge voltages of the cells Cn1˜Cn6 are greater than the preset threshold 1.75V, and the maximum value of the differences between the cell discharge voltages, that is the difference between the cell discharge voltages of the cells Cn2 and Cn5, is greater than the first predefined limit and less than the second predefined limit (e.g., within the range 20 mV˜35 mV), so that the series-coupled cells Cn1˜Cn6 constitute a lead-acid battery module in the second class.

In another embodiment, an average cell discharge voltage V_{DSG}_{_{—}}_{AVG} can be calculated for the cells in a lead-acid battery module and having the cell discharge voltages greater than the preset threshold, e.g., 1.75V. In one such embodiment, the grouping requirements of the method for grouping the lead-acid battery modules can be defined by referring the calculated average cell discharge voltage V_{DSG}_{_{—}}_{AVG} (hereinafter, average voltage V_{DSG}_{_{—}}_{AVG}) For example, if the cell discharge voltages of all the cells in a lead-acid battery module fall within a first range based on the average voltage V_{DSG}_{_{—}}_{AVG}, e.g., V_{DSG}_{_{—}}_{AVG}±10 mV, (if the maximum value of the differences between the average voltage V_{DSG}_{_{—}}_{AVG} and the cell discharge voltages is within a first limit, e.g., 10 mV), then the lead-acid battery module is classified to the first class. If the cell discharge voltages of one or more cells in the lead-acid battery module fall out of the first range and the cell discharge voltages of all the cells in the lead-add battery module fall within a second range based on the average voltage V_{DSG}_{_{—}}_{AVG}, e.g., V_{DSG}_{_{—}}_{AVG}±17.5 mV, (if the maximum value of the differences between the average voltage V_{DSG}_{_{—}}_{AVG} and the cell discharge voltages exceeds the first limit, e.g., 10 mV, and within a second limit, e.g., 17.5 mV), then the lead-acid battery module is classified to the second class. Classification to the third or the fourth class may be made accordingly based on the embodiments described herein.

Advantageously, during the battery manufacturing phase, based on the detection for statuses of the cells in the lead-acid battery modules, the voltage drops of the cells can be precisely identified, and the reduction of lifespan of the lead-acid battery pack which is caused by those voltage drops can be prevented. Moreover, by classifying the lead-acid battery modules according to the grouping requirements of the present teaching and according to the measured result of the cells in the lead-acid battery modules, the battery manufacturer can provide the lead-acid battery modules with different quality grades to meet various customer needs.

In the embodiments mentioned above, the lead-acid battery modules are discharged by the rated charge capacities, and then the cell discharge voltages of the lead-acid battery modules are measured after a period of time from the discharging of the lead-acid battery modules. However, the present teaching is not so limited. Moreover, it is understandable for one with ordinary skill in the art that other characteristic parameters of the cells in a lead-acid battery module can be measured to indicate the statuses of the cells described by the present teaching. By way of example, the voltage of each cell in the lead-acid battery module can be measured while the cells are being discharged. In this case, the measurement can be taken without waiting for a period of time from the discharging of the cells, and the classification of the lead-add battery module is conducted based on the differences between the voltages of the cells in the lead-acid battery module when being discharged. By way of another example, the internal resistance (which is derived from dividing the cell voltage by the cell current when the cell is being discharged) of each cell in the lead-acid battery module can be measured, and the classification of the lead-acid battery module is conducted based on the differences between the internal resistances of the cells in the lead-acid battery module.

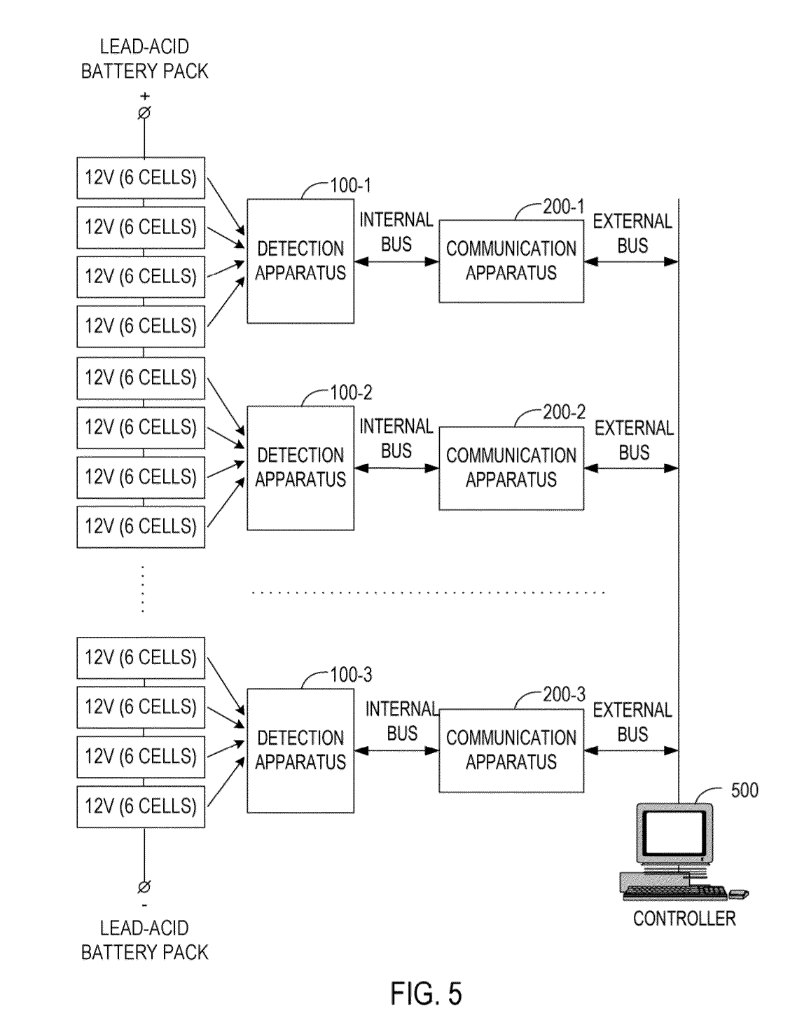

FIG. 5 illustrates a block diagram of an exemplary lead-acid battery grouping system for grouping multiple lead-acid battery packs, e.g., rated at 48V and assembled by four 12V lead-acid battery modules, in accordance with one embodiment of the present teaching. The lead-acid battery grouping system includes detection apparatuses 100-1, 100-2 and 100-3, similar to the detection apparatus 100 in FIG. 3, communication apparatuses 200-1, 200-2 and 200-3, similar to the communication apparatus 200 in FIG. 3, and a controller 500. The detection apparatuses 100-1, 100-2 and 100-3 transfer the measured results of cell discharge voltages of the cells in the lead-acid battery modules via internal buses to the communication apparatuses 200-1, 200-2 and 200-3 respectively, and the internal buses can be I2C (Inter-Integrated Circuit) buses, SPI (Serial Peripheral Interface) buses, or similar buses. The communication apparatuses 200-1, 200-2 and 200-3 transfer the measured results of cell discharge voltages of the cells in the lead-add battery modules via external buses to the controller 500, e.g., a PC (Personal Computer), and the external buses can be RS-485 buses, CAN (Controller Area Network) buses, or similar buses. The controller 500 may include a calculating unit (not shown) and a judging unit (not shown). The calculating unit calculates the differences between the cell discharge voltages of the cells in the lead-add battery modules according to the received measured result, and each of the differences is calculated between two cells in one lead-acid battery module. The judging unit classifies the lead-add battery modules according to the calculated differences and based on the aforementioned predefined grouping requirements. More specifically, the controller 500 checks whether each of the battery modules satisfies the aforementioned grouping requirements and which grouping requirement the battery module matches to.

While the foregoing description and drawings represent embodiments of the present teaching, it will be understood that various additions, modifications and substitutions may be made therein without departing from the spirit and scope of the principles of the present teaching as defined in the accompanying claims. One skilled in the art will appreciate that the embodiments described herein may be used with many modifications of form, structure, arrangement, proportions, materials, elements, and components and otherwise, used in the practice of the present teaching, which are particularly adapted to specific environments and operative requirements without departing from the principles of the present teaching. The presently disclosed embodiments are therefore to be considered in all respects as illustrative and not restrictive, the scope of the invention being indicated by the appended claims and their legal equivalents, and not limited to the foregoing description.

What is claimed is:

1. A method for grouping a plurality of battery modules in a battery pack, said method comprising:
measuring a plurality of characteristic parameters of a plurality of cells in a battery module of said plurality of battery modules to produce a measured result;
calculating a plurality of differences between said plurality of characteristic parameters according to said measured result; and
classifying said battery module according to said plurality of differences.

2. The method of claim 1, wherein said plurality of cells in said battery module comprises lead-acid battery cells.

3. The method of claim 1, wherein said calculating said plurality of differences comprises:
calculating each difference of said plurality of differences between two cells of said plurality of cells; and
wherein said classifying said battery module comprises:
classifying said battery module according to said each difference and a predefined grouping requirement.

4. The method of claim 3, further comprising determining a predefined grouping requirement comprising:
determining that said measured result indicates that each characteristic parameter of said plurality of characteristic parameters is equal to or greater than a preset threshold;
if said differences between said characteristic parameters corresponding to said plurality of cells in said battery module are equal to or less than a first predefined limit, classifying said battery module to a first class;
if a maximum value of said differences between said characteristic parameters corresponding to said plurality of cells in said battery module is greater than said first predefined limit, and equal to or less than a second predefined limit, classifying said battery module to a second class;
if said maximum value of said differences between said characteristic parameters corresponding to said plurality of cells in said battery module is greater than said second predefined limit, and equal to or less than a third predefined limit, classifying said battery module to a third class; and
if said maximum value of said differences between said characteristic parameters corresponding to said plurality of cells in said battery module is greater than said third predefined limit, classifying said battery module as an unqualified product.

5. The method of claim 1, wherein said measuring said plurality of characteristic parameters comprises:
fully charging said battery module;
discharging said battery module by a predetermined amount of charge;
after a period of time from said discharging of said battery module, measuring a plurality of cell discharge voltages of said plurality of cells in said battery module.

6. The method as claimed in claim 1, further comprising:
detecting temperature of said battery modules to ensure a comparable temperature condition for said measuring of said characteristic parameters in said battery modules.

7. The method as claimed in claim 1, further comprising:
adjusting a manufacturing process of said battery module based on said classifying of said battery module.

8. The method as claimed in claim 7, wherein said adjusting said manufacturing process of said battery module comprises:
adjusting the amount of acid injection of said plurality of cells in said battery module.

9. A system for grouping a plurality of battery modules in a battery pack, said system comprising:
a detection apparatus configured to measure a plurality of characteristic parameters of a plurality of cells in a battery module of said plurality of battery modules to produce a measured result, and configured to calculate a plurality of differences between said plurality of characteristic parameters according to said measured result; and
a controller configured to classify said battery module according to said plurality of differences.

10. The system of claim 9, wherein said plurality of cells in said battery module comprises lead-acid battery cells.

11. The system of claim 9, wherein said controller comprises:
a calculating unit configured to calculate said plurality of differences between said characteristic parameters according to said measured result, wherein each difference is calculated between two cells of said plurality of cells; and
a judging unit configured to classify said battery module according to said differences and a predefined grouping requirement.

12. The system of claim 11, wherein said judging unit is further configured to:
classify said battery module if said measured result indicates that each characteristic parameter of said plurality of characteristic parameters is equal to or greater than a preset threshold;
classify said battery module to a first class if said differences between said characteristic parameters corresponding to said plurality of cells in said battery module are equal to or less than a first predefined limit;
classify said battery module to a second class if a maximum value of said differences between said characteristic parameters corresponding to said plurality of cells in said battery module is greater than said first predefined limit, and equal to or less than a second predefined limit;
classify said battery module to a third class if said maximum value of said differences between said characteristic parameters corresponding to said plurality of cells in said battery module is greater than said second predefined limit, and equal to or less than a third predefined limit; and
classify said battery module as an unqualified product if said maximum value of said differences between said characteristic parameters corresponding to said plurality of cells in said battery module is greater than said third predefined limit.

13. The system of claim 9, further comprising:
a communication apparatus, coupled between said detection apparatus and said controller, configured to transfer said measured result of said plurality of characteristic parameters from said detection apparatus to said controller.

14. The system of claim 9, wherein said detection apparatus is further configured to detect temperature of said battery modules to ensure a comparable temperature condition to measure said plurality of characteristic parameters in said battery modules.

15. A system for grouping a plurality of battery modules in a battery pack, said system comprising:
a plurality of detecting terminals each coupled to a cell of a plurality of cells in a battery module of said plurality of battery modules; and
a detection circuit, coupled to said plurality of detecting terminals, the detection circuit comprising:
a detection unit configured to measure a plurality of characteristic parameters of said plurality of cells to produce a measured result, and configured to calculate a plurality of differences between said plurality of characteristic parameters according to said measured result; and
a controller configured to classify said battery module to a corresponding class of a plurality of classes according to said plurality of differences.

16. The system of claim 15, wherein said plurality of cells in said battery module comprises lead-acid battery cells.

17. The system of claim 15, wherein said controller comprises:
a calculating unit configured to calculate said differences between said plurality of characteristic parameters according to said measured result, wherein each difference is calculated between two cells of said plurality of cells; and
a judging unit configured to classify said battery module according to said differences and a predefined grouping requirement.

18. The system of claim 15, wherein each corresponding class comprises a first limit and a second limit greater than said first limit, and wherein said controller is configured to classify said battery module to said corresponding class if a maximum value of said differences between said plurality of characteristic parameters of said plurality of cells in said battery module is greater than a corresponding first limit and less than a corresponding second limit.

19. The system of claim 15, wherein said detection circuit further comprises:
a communication unit, coupled to said detection unit and said controller, configured to transfer said measured result from said detection unit to said controller.

20. The system of claim 15, wherein said detection circuit is further configured to detect temperature of said battery modules to ensure a comparable temperature condition to measure said plurality of characteristic parameters in said battery modules.
